(19) United States
(12) Patent Application Publication
(10) Pub. No.: US 2026/0145292 A1
(43) Pub. Date: May 28, 2026

(54) PROCESSING METHOD, PROCESSING DEVICE, AND SUBSTRATE MANUFACTURING METHOD

(71) Applicant: DISCO CORPORATION, Tokyo (JP)

(72) Inventors: Nobuki Kakiuchi, Tokyo (JP); Mami Saeki, Tokyo (JP); Maho Hirakawa, Tokyo (JP)

(21) Appl. No.: 19/402,253

(22) Filed: Nov. 26, 2025

(30) Foreign Application Priority Data
Nov. 27, 2024 (JP) 2024-206251

(51) Int. Cl. B24B 37/005

(52) U.S. Cl. CPC B24B 37/005; H10P 74/207; H10P 95/02

(57) ABSTRACT

A processing method includes: acquiring data on an impurity concentration of a workpiece; and planarizing one surface of the workpiece held on a holding table by grinding or polishing the one surface with a planarization processor, and in the planarizing, the one surface of the workpiece is planarized based on the data acquired in the acquiring.

### CROSS-REFERENCE TO RELATED APPLICATIONS

This application is based on and claims priority under 35 USC 119 from Japanese Patent Application No. 2024-206251 filed on Nov. 27, 2024, the contents of which are incorporated herein by reference.

### TECHNICAL FIELD

The present disclosure relates to a processing method and a processing device.

### BACKGROUND ART

A semiconductor wafer is subjected to front surface polishing after being ground to a predetermined thickness in a manufacturing process thereof. Regarding such polishing, for example, Patent Literature 1 discloses a technique of changing a shape of a polishing pad in a radial direction according to a thickness distribution of a wafer in the radial direction in order to uniform a thickness of the wafer after polishing.

Patent Literature 1: JP2015-223636A

### SUMMARY OF INVENTION

A SiC single crystal is generally doped with an impurity such as nitrogen in order to impart conductivity in a growth process. When a workpiece doped with impurities is polished, a polishing rate changes according to an impurity concentration, and thus the workpiece may not be planarized to a uniform thickness in the polishing.

The present disclosure provides a processing method and a processing device capable of planarizing a workpiece doped with impurities to a uniform thickness.

An aspect of the present disclosure is related to a processing method including:
an impurity concentration acquisition step of acquiring data on an impurity concentration of a workpiece; and
a planarization step of planarizing one surface of the workpiece held on a holding table by grinding or polishing the one surface with a planarization processing unit, in which
the one surface of the workpiece is planarized in the planarization step based on the data acquired in the impurity concentration acquisition step.

An aspect of the present disclosure is related to a substrate manufacturing method for manufacturing a substrate from the workpiece by planarizing the one surface of the workpiece by the processing method.

An aspect of the present disclosure is related to a processing device for processing one surface of a workpiece held on a holding table, and the processing device includes:
a spindle extending in a predetermined direction and rotatably provided;
a mount fixed to a tip end of the spindle; and
a planarization processing unit fixed to the mount and configured to grind or polish the one surface of the workpiece to planarize the one surface, in which
the processing device planarizes the one surface of the workpiece by the planarization processing unit based on data on an impurity concentration of the workpiece.

### BRIEF DESCRIPTION OF DRAWINGS

FIG. 1 is a schematic view of an ingot 1 and a wafer 2 peeled from the ingot 1.

FIGS. 2A and 2B are front views of the ingot 1 (wafer 2), and show an example of a distribution of an impurity concentration in the ingot 1 (wafer 2).

FIG. 3 is a flowchart showing a processing method according to a first embodiment.

FIG. 4 is a view schematically showing a resistance value measuring instrument 11 capable of performing an impurity concentration acquisition step S10.

FIG. 5 is a view schematically showing a detection device 20 capable of performing the impurity concentration acquisition step S10.

FIG. 6 is a schematic view of a laser beam irradiation mechanism 30 for performing a peeling start point forming step S20.

FIG. 7 is a view showing a state where a laser beam is applied from a front surface 1a of the ingot 1 by the laser beam irradiation mechanism 30.

FIG. 8 is a schematic view (part 1) of a peeling device 40 for performing a peeling step S30.

FIG. 9 is a schematic view (part 2) of the peeling device 40 for performing the peeling step S30.

FIG. 10 shows a modification of an ultrasonic oscillation unit 42 of the peeling device 40.

FIG. 11 is a perspective view of a grinding device 50 for performing a grinding step S40.

FIG. 12 is a schematic configuration diagram showing a configuration of a polishing device 60 for performing a polishing step S50.

FIG. 13 is a flowchart showing a processing method according to a second embodiment.

FIG. 14 is a schematic configuration diagram showing a configuration of a dressing mechanism 80 for performing a shaping step S45.

FIG. 15 is a schematic view showing an example of a shaped polishing pad 64.

FIG. 16 is a schematic view showing another example of the shaped polishing pad 64.

### DESCRIPTION OF EMBODIMENTS

Hereinafter, embodiments of a processing method and a processing device of the present disclosure will be described with reference to the accompanying drawings.

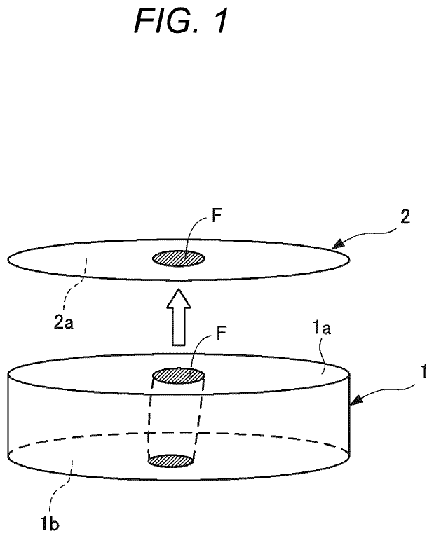

FIG. 1 is a schematic view of an ingot 1 and a wafer 2 peeled from the ingot 1.

The ingot 1 is, for example, a Si single crystal ingot or a SiC single crystal ingot. The ingot 1 is formed in a cylindrical shape. The wafer 2, which is a disk-shaped substrate, is manufactured by peeling the wafer 2 from a front surface 1a of the ingot 1. In FIG. 1, reference numeral 2a denotes a peeling surface 2a of the wafer 2 peeled from the front surface 1a of the ingot 1, and reference numeral 1b denotes a back surface 1b opposite to the front surface 1a in a thickness direction of the ingot 1.

The ingot 1 is doped with impurities in order to impart conductivity in a growth process. For example, in a case of the SiC single crystal ingot, nitrogen is doped as an impurity. Although an amount of the impurity doped in the ingot 1 is controlled, an impurity concentration varies depending on the ingot 1. That is, an average value of the impurity concentration is different for each ingot 1.

The impurity is not uniformly doped in the ingot 1, and a distribution of the impurity concentration is generated. Since the distribution of the impurity concentration is different according to a position of the ingot 1 in the thickness direction, a plurality of wafers 2 peeled from the ingot 1 have different average values of the impurity concentration and different distributions of the impurity concentration.

The distribution of the impurity concentration in the ingot 1 is specifically described, a facet region F, which is a flat region at the atomic level, is locally formed in the ingot 1 in a growth process of a single crystal. The facet region F is formed in a columnar shape from the front surface 1a to the back surface 1b of the ingot 1. Since the impurity is relatively more likely to be taken into the facet region F than the other portion (also referred to as a non-facet region), an impurity concentration of the facet region F is higher than an impurity concentration of the non-facet region.

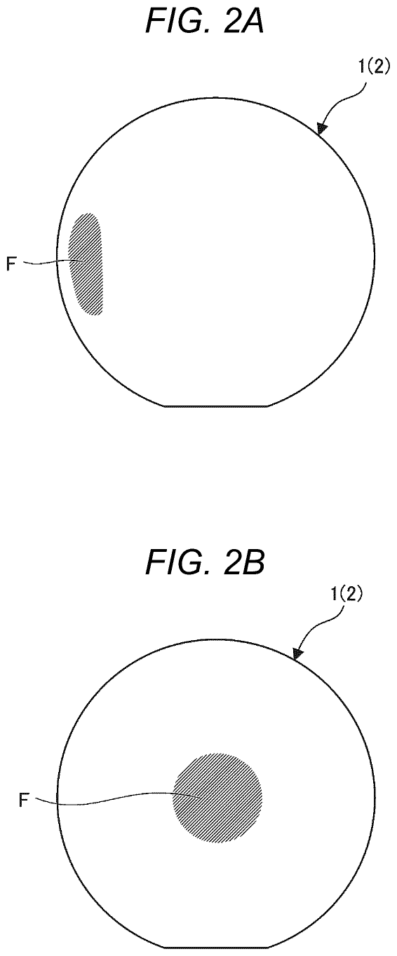

FIGS. 2A and 2B are front views of the ingot 1 (wafer 2), and show an example of the distribution of the impurity concentration in the ingot 1 (wafer 2). A hatched region indicates the facet region F. In the example shown in FIG. 2A, the facet region F is formed near an outer edge of the ingot 1 (wafer 2) on the left side in the drawing, and the other region is the non-facet region. In another example shown in FIG. 2B, the facet region F is formed in a central portion of the ingot 1 (wafer 2), and the other region is the non-facet region.

### First Embodiment

First, a first embodiment of the processing method of the present disclosure will be described.

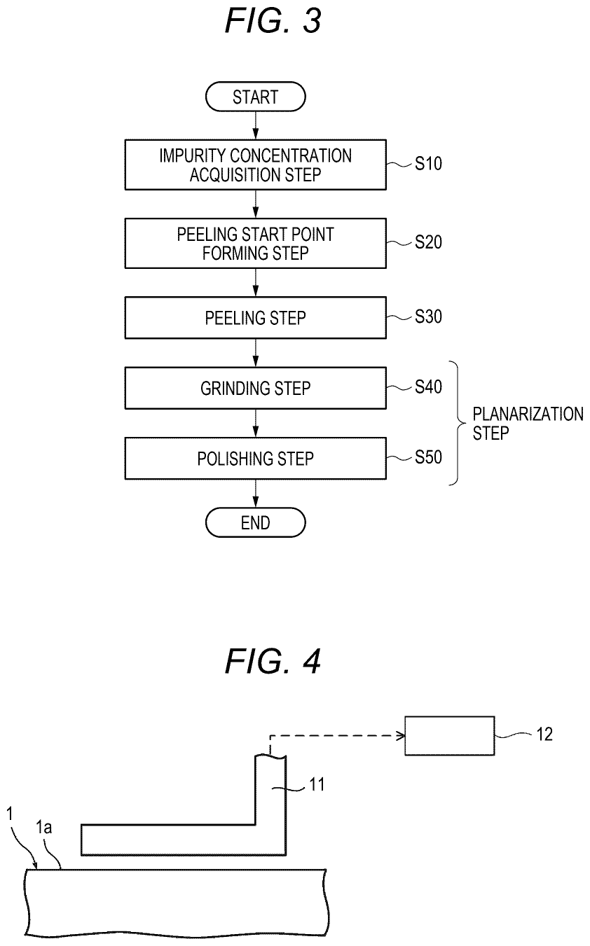

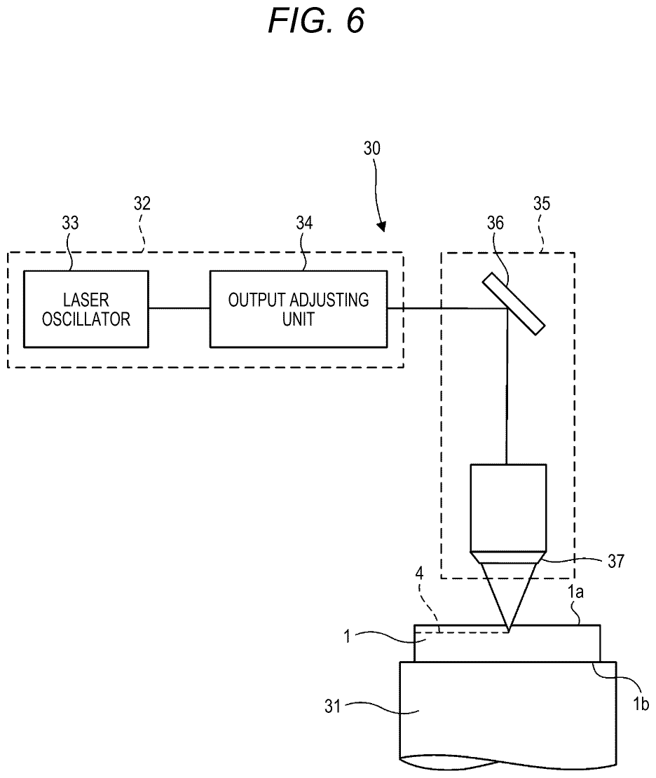

FIG. 3 is a flowchart showing the processing method according to the first embodiment. The processing method according to the first embodiment includes an impurity concentration acquisition step S10 of acquiring data on the impurity concentration of the ingot 1, a peeling start point forming step S20 of forming a peeling start point 4 (see FIG. 6) in the ingot 1, a peeling step S30 of peeling the wafer 2 from the ingot 1, a grinding step S40 of grinding the peeling surface 2a of the peeled wafer 2, and a polishing step S50 of polishing the peeling surface 2a of the ground wafer 2. The grinding step S40 and the polishing step S50 may each be referred to as a planarization step. The ingot 1 and the wafer 2 are objects to be processed in the processing method, and may each be referred to as a “workpiece”.

### Impurity Concentration Acquisition Step

In the impurity concentration acquisition step S10, the data on the impurity concentration of the ingot 1 is acquired. The data on the impurity concentration includes, for example, the average value of the impurity concentration and/or the distribution of the impurity concentration. Since the wafer 2 is peeled from the ingot 1, it can also be said that the impurity concentration acquisition step S10 acquires data on an impurity concentration of the wafer 2.

Specifically, in the impurity concentration acquisition step S10, an electric resistance value of the front surface 1a of the ingot 1 is measured, and the data on the impurity concentration is acquired based on the electric resistance value.

FIG. 4 is a view schematically showing a resistance value measuring instrument 11 capable of performing the impurity concentration acquisition step S10. The resistance value measuring instrument 11 measures the electric resistance value of the front surface 1a of the ingot 1. The resistance value measuring instrument 11 may be either a non-contact type or a contact type. The electric resistance value measured by the resistance value measuring instrument 11 may be an electric resistance or an electric resistivity.

In the impurity concentration acquisition step S10, the resistance value measuring instrument 11 is positioned to face the front surface 1a of the ingot 1, and measures the electric resistance value. The resistance value measuring instrument 11 may be movable up and down by an elevating unit, or may be movable in a direction (horizontal direction) parallel to the front surface 1a. The resistance value measuring instrument 11 transmits a signal including the measured electric resistance value to a control device 12.

The control device 12 includes a processor that performs calculation processing according to a program, and a memory such as a read only memory (ROM) and a random access memory (RAM). Based on the received signal including the electric resistance value, the control device 12 acquires the data on the impurity concentration by performing calculation or by referring to a map or the like created in advance.

When another example of the impurity concentration acquisition step S10 is described, in the impurity concentration acquisition step S10, the front surface 1a of the ingot 1 may be irradiated with an excitation light having a predetermined wavelength, and the data on the impurity concentration is acquired based on a predetermined detection result of a fluorescence generated by the excitation light. Although details will be described later, the predetermined detection result is, for example, the number of photons of a light having a wavelength in an infrared region of the fluorescence or a luminance of the fluorescence.

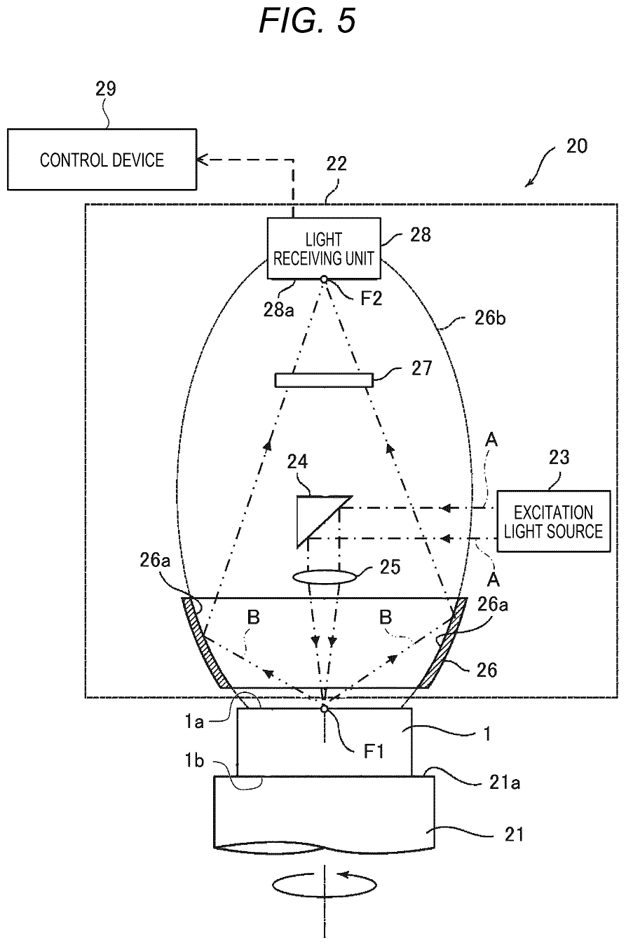

FIG. 5 is a view schematically showing a detection device 20 capable of performing the impurity concentration acquisition step S10. The detection device 20 includes a disk-shaped holding table 21 that holds the ingot 1, a detection unit 22 provided above the holding table 21, and a control device 29.

The holding table 21 holds the ingot 1 placed on a holding surface 21a under suction by a suction source (not shown). The holding table 21 is rotatable, by a spindle, a motor, or the like, about a central axis extending in a direction (vertical direction) orthogonal to the holding surface 21a. The holding table 21 is movable in a direction (horizontal direction) parallel to the holding surface 21a and/or in the vertical direction by a ball screw, a motor, or the like.

The detection unit 22 includes an excitation light source 23, a mirror 24, a condenser lens 25, an annular and elliptical mirror 26 having a reflection surface 26a inside, a filter 27, and a light receiving unit 28. The detection unit 22 is movable along the horizontal direction and/or the vertical direction by a ball screw, a motor, or the like.

The excitation light source 23 includes, for example, a GaN-based light-emitting element, and irradiates the side mirror 24 with an excitation light A having a wavelength (for example, 365 nm) absorbed by the ingot 1. The excitation light A reflected by the mirror 24 is condensed by the condenser lens 25 below.

The reflection surface 26a of the elliptical mirror 26 corresponds to a part of a curved surface of a spheroid obtained by rotating an ellipse 26b, which has a major axis extending in the vertical direction and a minor axis extending in the horizontal direction, around the major axis. The elliptical mirror 26 has two focal points F1 and F2, and condenses a light generated from one (for example, the focal point F1) to the other (for example, the focal point F2). The condenser lens 25 is designed such that the focal point thereof substantially coincides with the focal point F1. That is, the excitation light A is condensed at the focal point F1.

The filter 27 is provided in an optical path between the focal point F1 and the focal point F2 of the elliptical mirror 26. In the detection unit 22, a light generated at the focal point F1 and reflected by the elliptical mirror 26 travels toward the focal point F2 through the filter 27. The filter 27 includes, for example, an infrared filter (IR filter) through which a light having a wavelength of 750 nm or more transmits and which blocks a light having a wavelength of less than 750 nm.

The light receiving unit 28 is provided such that a center of a light receiving surface 28a coincides with the focal point F2 of the elliptical mirror 26. The light receiving unit 28 includes, for example, a photomultiplier tube or the like that outputs an electric signal indicating the number of photons of a light having a wavelength of a predetermined value or less (for example, 900 nm or less, 1200 nm or less, or 1500 nm or less) when the light is received.

The control device 29 includes a processor that performs calculation processing according to a program, and a memory such as a ROM and a RAM. Based on the detection result of the light receiving unit 28, the control device 29 acquires the data on the impurity concentration by performing calculation or by referring to a map or the like created in advance.

The regions having different impurity concentrations (for example, the facet region and the non-facet region) of the ingot 1 are specified using the detection device 20, for example, in the following order. First, in a state where the back surface 1b side of the ingot 1 is held on the holding surface 21a of the holding table 21, a position of the holding table 21 in the horizontal direction and a position of the detection unit 22 in the vertical direction are adjusted such that the focal point F1 of the elliptical mirror 26 coincides with a point on the front surface 1a of the ingot 1. Specifically, the holding table 21 and the detection unit 22 are moved such that the focal point F1 coincides with any of a plurality of coordinates indicating a plurality of regions included in the front surface 1a of the ingot 1 on a coordinate plane parallel to the holding surface 21a.

Next, the excitation light source 23 emits the excitation light A. When the ingot 1 is irradiated with the excitation light A via the mirror 24 and the condenser lens 25, the ingot 1 absorbs the excitation light A and generates a fluorescence B at the focal point F1. For example, when the wavelength of the excitation light A is 365 nm, the excitation light A enters from the front surface 1a of the ingot 1 to a depth of about 10 μm. The fluorescence B is generated from a plate-shaped region having a thickness of about 10 μm on the front surface 1a side of the ingot 1. The fluorescence B generated at the focal point F1 reaches the filter 27 via the elliptical mirror 26. Only a light having a wavelength in the IR region (for example, a wavelength of 750 nm or more) of the fluorescence B transmits through the filter 27. Accordingly, the light receiving unit 28 receives the light having the wavelength in the IR region and generates an electric signal indicating the number of photons. Further, the excitation light source 23 emits the excitation light A in a state where the holding table 21 and the detection unit 22 are relatively moved such that the focal point F1 coincides with each of the remaining one of the plurality of coordinates.

As a result, the same number of electric signals indicating the number of photons of the light having the wavelength in the IR region as the plurality of coordinates are generated. The number of photons decreases in regions of the ingot 1 where the impurity concentration is higher. Therefore, in the detection device 20, it is possible to specify regions having different impurity concentrations in the ingot 1.

The detection device 20 described above acquires the data on the impurity concentration based on the number of photons of the fluorescence B generated by the excitation light A, but is not limited thereto, and may acquire the data on the impurity concentration based on a luminance of the fluorescence B generated by the excitation light A. Specifically, the light receiving unit 28 may generate an electric signal indicating the luminance of the fluorescence B that has passed through the filter 27, and the control device 29 may acquire the data on the impurity concentration based on a magnitude of the luminance of the received fluorescence B.

When another example of the impurity concentration acquisition step S10 is described, the ingot 1 may be irradiated with a light having permeability, and the data on the impurity concentration may be acquired based on a transmittance of the light. It can be seen that the region having a low light transmittance is the facet region F having a high impurity concentration.

Three examples of the impurity concentration acquisition step S10 have been described above, but the present disclosure is not limited thereto, and the data on the impurity concentration may be acquired by any method. For example, the impurity concentration acquisition step S10 based on the transmittance of the light may be performed at the time of the peeling start point forming step S20 described later.

A laser beam irradiation mechanism 30 performing the peeling start point forming step S20 positions a laser beam having a wavelength transmittable through the ingot 1 and applies the laser beam to a position deeper than the front surface 1a of the ingot 1. In general, when the impurity concentration of the ingot 1 is high, a transmittance of the laser beam is low, and an output of the laser beam required to form the peeling start point 4 is high. On the other hand, when the impurity concentration of the ingot 1 is low, the transmittance of the laser beam is high, and the output of the laser beam required to form the peeling start point 4 is low. That is, the transmittance of the light in the ingot 1 can be grasped based on the output of the laser beam required to form the peeling start point 4 in the ingot 1. In the impurity concentration acquisition step S10, the data on the impurity concentration of the ingot 1 may be acquired based on the transmittance of the light obtained in this manner.

As described above, since the impurity concentration of the ingot 1 is different according to the position in the thickness direction, the plurality of peeled wafers 2 have different distributions of the impurity concentration and/or different average values of the impurity concentration. Therefore, the impurity concentration acquisition step S10 is performed every time a predetermined number of (for example, one or five) wafers 2 are peeled from the ingot 1. Accordingly, in the impurity concentration acquisition step S10, the distribution of the impurity concentration and/or the average value of the impurity concentration for each wafer 2 can be accurately acquired.

### Peeling Start Point Forming Step

FIG. 6 is a schematic view of the laser beam irradiation mechanism 30 for performing the peeling start point forming step S20. The laser beam irradiation mechanism 30 applies the laser beam to the ingot 1 fixed to the holding table 31 from the front surface 1a side to form the peeling start point 4 in the ingot 1.

Specifically, the laser beam irradiation mechanism 30 includes a laser beam generating unit 32 and a condenser (laser head) 35. Although not shown, an imaging unit, which is adjacent to the condenser 35 and includes an optical unit such as a microscope or a charge coupled device (CCD) camera, is attached to the laser beam irradiation mechanism 30.

The laser beam generating unit 32 includes a laser oscillator 33 that oscillates a YAG laser or a YVO4 laser, and an output adjusting unit 34. The laser oscillator 33 has a Brewster window, and the laser beam emitted from the laser oscillator 33 is a linearly polarized laser beam. A pulsed laser beam, which is adjusted to a predetermined power by the output adjusting unit 34 of the laser beam generating unit 32, is reflected by a mirror 36 of the condenser 35, and then is applied by a condenser lens 37 at a condenser point inside the ingot 1. The front surface 1a of the ingot 1 is polished into a mirror finish as the front surface 1a is a surface to be applied with the laser beam.

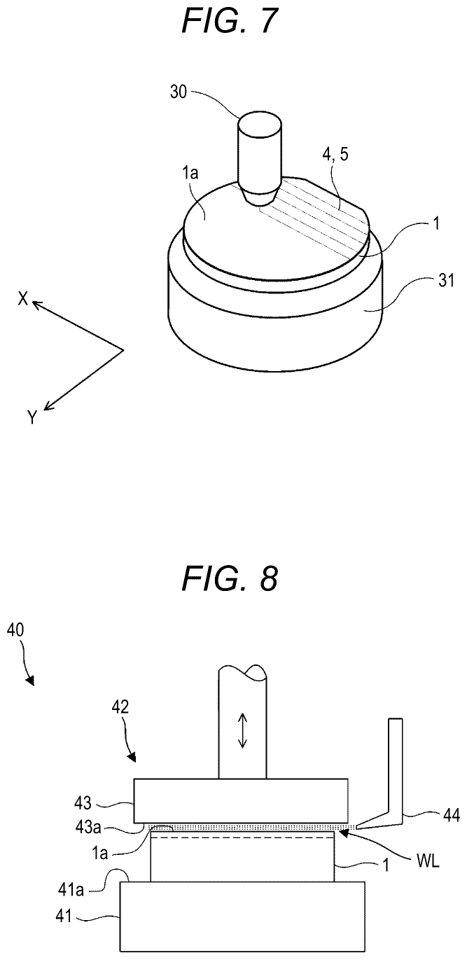

FIG. 7 is a view showing a state where the laser beam is applied from the front surface 1a of the ingot 1 by the laser beam irradiation mechanism 30. The laser beam irradiation mechanism 30 forms the peeling start point 4 including a plurality of modified regions 5 inside the ingot 1.

Specifically, the laser beam irradiation mechanism 30 positions, at a position deeper than the front surface 1a of the ingot 1, the condenser point of the laser beam having a wavelength that transmits through the ingot 1 held on the holding table 31, and forms the modified regions 5 by condensing the laser beam and applying the laser beam from the front surface 1a of the ingot 1. Then, the laser beam irradiation mechanism 30 repeats processing of feeding the ingot 1 such that the condenser point moves from one end to the other end of the ingot 1 along an X-axis direction to form the modified regions 5 along the X-axis direction, subsequently moving the ingot 1 by a predetermined amount in an Y-axis direction, and then feeding the ingot 1 such that the condenser point moves from the other end to the one end of the ingot 1 along the X-axis direction to form the modified regions 5 along the X-axis direction. Accordingly, the peeling start point 4 including the modified regions 5 and cracks extending from the modified regions 5 is formed inside the ingot 1.

As described above, in the peeling start point forming step S20, the laser beam irradiation mechanism 30 applies the condenser point of the laser beam to the ingot 1, positions the condenser point at a position deeper than the front surface 1a of the ingot 1, and applies the laser beam from the front surface 1a, the peeling start point 4 including the modified regions 5 and the cracks extending from the modified regions 5 is formed.

### Peeling Step

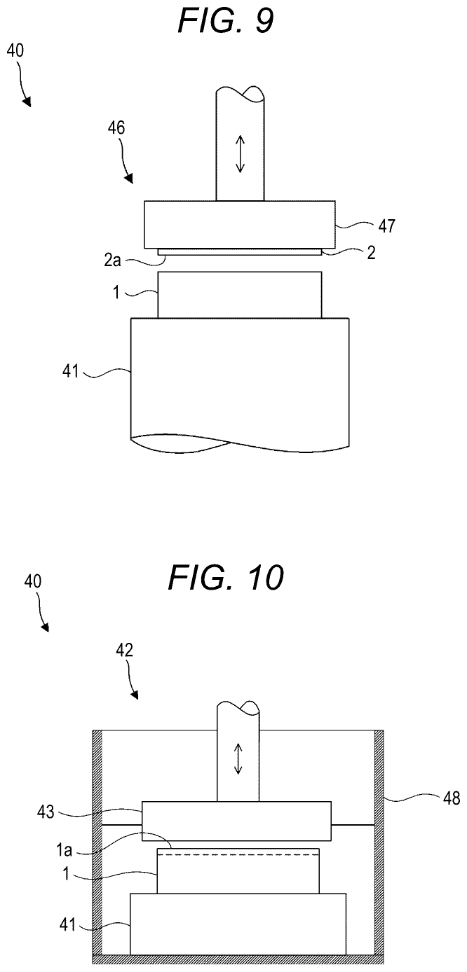

FIGS. 8 and 9 are schematic views of a peeling device 40 for performing the peeling step S30. The peeling device 40 includes a disk-shaped holding table 41 that holds the ingot 1 with the front surface 1a of the ingot 1 facing upward, an ultrasonic oscillation unit 42 that applies ultrasonic waves to the ingot 1, and a peeling unit 46 that peels the wafer 2 from the ingot 1. FIG. 6 shows the ultrasonic oscillation unit 42, and FIG. 7 shows the peeling unit 46.

For example, the holding table 41 holds the ingot 1 via an epoxy resin-based adhesive, or holds the ingot 1 under suction by a suction force generated by the suction source (not shown). The holding table 41 is rotatable, by a spindle, a motor, or the like, about a central axis extending in a direction (vertical direction) orthogonal to a holding surface 41a.

As shown in FIG. 8, the ultrasonic oscillation unit 42 includes an ultrasonic vibrator 43 that has an end surface 43a facing the front surface 1a of the ingot 1 held on the holding table 41 and applies ultrasonic waves to the ingot 1, and a liquid supply nozzle 44 that supplies a liquid (for example, pure water) between the front surface 1a of the ingot 1 and the end surface 43a of the ultrasonic vibrator 43. Positions of the ultrasonic vibrator 43 and the liquid supply nozzle 44 in the vertical direction can be adjusted by an elevating mechanism such as an air cylinder, a ball screw, and a motor.

The ultrasonic vibrator 43 is positioned at a position where a slight gap (for example, 0.6 mm) is provided between the end surface 43a and the front surface 1a of the ingot 1. While the ultrasonic waves are being applied to the ingot 1, the liquid supply nozzle 44 continuously supplies the liquid to the gap between the end surface 43a of the ultrasonic vibrator 43 and the front surface 1a of the ingot 1 to form a liquid layer WL. The ultrasonic waves emitted from the ultrasonic vibrator 43 are transmitted to the ingot 1 via the liquid layer WL to extend the cracks at the peeling start point 4 formed in the ingot 1. Accordingly, a strength of the peeling start point 4 decreases.

As shown in FIG. 9, the peeling unit 46 includes a suction pad 47 for holding and suctioning the wafer 2 to be peeled from the ingot 1. A position of the suction pad 47 in the vertical direction can be adjusted by an elevating mechanism such as an air cylinder, a ball screw, and a motor. After the ultrasonic waves are applied to the entire front surface 1a of the ingot 1, the peeling unit 46 is moved to a position facing the holding table 41 at the same time as or after the ultrasonic oscillation unit 42 is separated from the holding table 41. Then, the peeling unit 46 causes the suction pad 47 to suction the front surface 1a of the ingot 1 and moves the suction pad 47 upward, thereby peeling, as the wafer 2, a plate-shaped object including the front surface 1a of the ingot 1 from the peeling start point 4 of the ingot 1.

As described above, in the peeling step S30, the wafer 2 is peeled from the peeling start point 4 of the ingot 1 by the peeling device 40.

FIG. 10 shows a modification of the ultrasonic oscillation unit 42 of the peeling device 40. The ultrasonic oscillation unit 42 of the modification includes a water tank 48 in which a liquid is stored, and the ultrasonic vibrator 43 and the ingot 1 are disposed in the liquid. That is, ultrasonic waves emitted from the ultrasonic vibrator 43 are applied to the ingot 1 via the liquid stored in the water tank 48. With such a configuration, it is also possible to promote the extension of the cracks at the peeling start point 4 formed in the ingot 1.

### Grinding Step

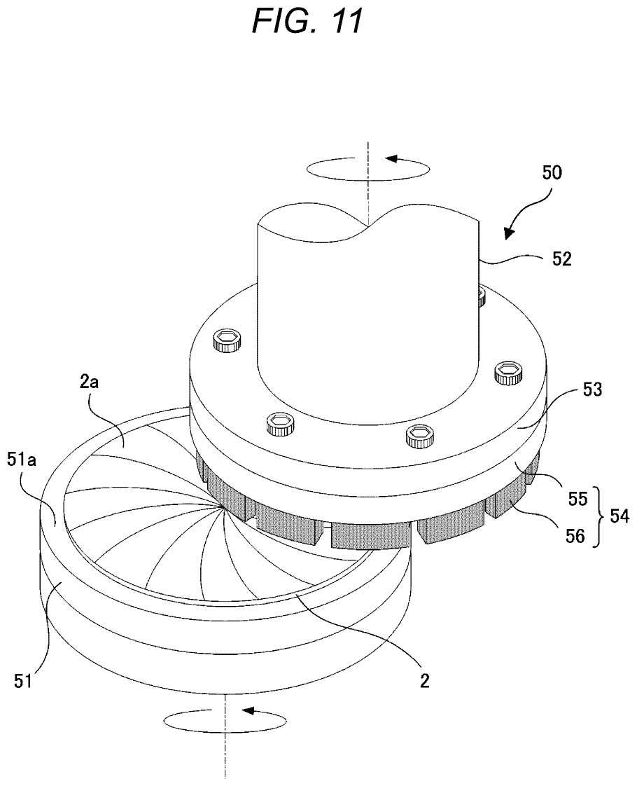

FIG. 11 is a perspective view of a grinding device 50 for performing the grinding step S40. The grinding device 50 holds the wafer 2 peeled in the peeling step S30 on a holding table 51 such that the peeling surface 2a faces upward, and grinds and planarizes the exposed peeling surface 2a of the wafer 2.

The holding table 51 holds the ingot 1 placed on a holding surface 51a under suction by a suction source (not shown). The holding table 51 is rotatable, by a spindle, a motor, or the like, about a central axis extending in a direction (vertical direction) orthogonal to the holding surface 51a. The holding table 51 may be movable in a direction (horizontal direction) parallel to the holding surface 51a and/or in the vertical direction.

The holding table 51 may be provided with a cooling flow path (not shown) through which cooling water flows. The cooling water is not directly supplied to the wafer 2, and heat exchange is performed between the wafer 2 and the cooling water flowing through a cooling flow path, thereby preventing a temperature rise of the wafer 2 during processing.

The grinding device 50 includes a spindle 52, which extends in the vertical direction and is rotatable by a drive source such as a motor, a disk-shaped mount 53 fixed to a lower end of the spindle 52, and a grinding wheel 54 fixed to a lower end of the mount 53. The spindle 52 is movable up and down in the vertical direction with respect to the holding table 51.

The grinding wheel 54 includes an annular wheel base 55 made of a metal material such as stainless steel and aluminum, and a plurality of grindstones 56 annularly arranged on a lower surface of the wheel base 55. The grindstones 56 contain a binder formed of ceramics, resin, a metal material, or the like, and numerous abrasive grains such as diamonds dispersed and fixed in the binder.

In the grinding step S40, the peeling surface 2a of the wafer 2 held on the holding table 51 is ground by the grindstones 56. The grinding step S40 is performed by, for example, in-feed grinding as shown in FIG. 11. In the in-feed grinding, a positional relationship between the holding table 51 and the grinding wheel 54 is adjusted such that a center of the wafer 2 held by the holding table 51 coincides with a track of the grindstones 56. In the in-feed grinding, the grinding wheel 54 is lowered along a processing-feed direction (vertical direction) parallel to a rotation axis of the spindle 52 while rotating the holding table 51 and the grinding wheel 54. Accordingly, a lower surface of the grindstones 56 comes into contact with an upper surface (peeling surface 2a) of the wafer 2, and the wafer 2 is ground.

The grinding step S40 may be performed by creep feed grinding. In the creep feed grinding, the positional relationship between the holding table 51 and the grinding wheel 54 is adjusted such that the grindstones 56 are positioned outside the wafer 2 and the lower surface of the grindstones 56 is positioned below the peeling surface 2a of the wafer 2. In the creep feed grinding, the grinding wheel 54 is moved in a processing-feed direction (horizontal direction) parallel to the holding surface 51a of the holding table 51 while being rotated. Accordingly, a side surface of the grindstone 56 mainly comes into contact with the peeling surface 2a of the wafer 2, and the wafer 2 is ground.

### Polishing Step

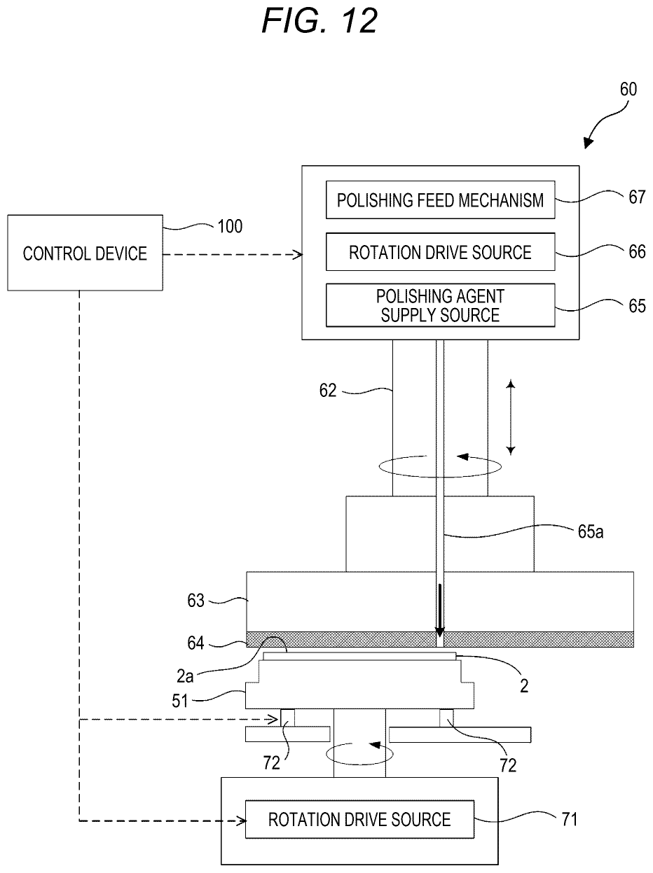

FIG. 12 is a schematic configuration diagram showing a configuration of a polishing device 60 for performing the polishing step S50. The polishing device 60 polishes and planarizes the peeling surface 2a of the wafer 2 ground in the grinding step S40. Here, a case where the holding table that holds the wafer 2 is the holding table 51 used in the grinding step S40 will be described as an example.

The polishing device 60 includes a rotation drive source 71, which has a motor and causes the holding table 51 to rotate about a central axis extending in the vertical direction, and an inclination adjustment mechanism 72 adjusting an inclination of the holding table 51. The inclination adjustment mechanism 72 includes, for example, two movable support portions and one fixed support portion, and supports the holding table 51 at three points from below. The inclination adjustment mechanism 72 adjusts the inclination of the holding table 51 by inclining the holding table 51 with the fixed support portion as a fulcrum by vertical movement of the two movable support portions.

The polishing device 60 includes a spindle 62 extending in the vertical direction and rotatably provided, a disk-shaped mount 63 fixed to a lower end of the spindle 62, a polishing pad 64 having a polishing surface and fixed to a lower end of the mount 63, a polishing agent supply source 65 that supplies a polishing agent to a processing point, when the wafer 2 is polished, through a through hole 65a, a rotation drive source 66 having a motor and rotating the spindle 62, and a polishing feed mechanism 67 that moves the spindle 62 in the vertical direction.

The polishing pad 64 has a disk shape larger than the holding surface 51a of the holding table 51. The polishing pad 64 includes a fixed abrasive grain layer in which abrasive grains are dispersed. The fixed abrasive grain layer is produced, for example, by impregnating a polyester nonwoven fabric with a urethane solution in which abrasive grains having an average particle diameter of 0.4 μm to 0.6 μm are dispersed, and then drying the polyester nonwoven fabric. The abrasive grains dispersed inside the fixed abrasive grain layer are made of a material such as SiC, CBN, diamonds, or metal oxide fine particles. As the metal oxide fine particles, fine particles made of SiO₂, CeO₂, ZrO₂, Al₂O₃, or the like are used. The fixed abrasive grain layer is flexible and slightly bends according to a pressure applied when polishing the wafer 2. The polishing pad 64 is an example of a planarization processing unit in the present disclosure.

The polishing pad 64 may be provided with a cooling flow path (not shown) through which the cooling water for cooling the wafer 2 flows. The cooling water is not directly supplied to the wafer 2, and heat exchange is performed between the wafer 2 and the cooling water flowing through the cooling flow path, thereby preventing a temperature rise of the wafer 2 during processing.

Center positions of the spindle 62, the mount 63, and the polishing pad 64 in the radial direction substantially coincide with each other, that is, the rotation axes thereof substantially coincide with each other. The rotation drive source 66 rotates the spindle 62 about a rotation axis extending in the vertical direction to rotate the mount 63 and the polishing pad 64 fixed to the lower end of the spindle 62. The polishing feed mechanism 67 moves the polishing pad 64 toward or away from the holding table 51 (wafer 2) by moving the spindle 62 in the vertical direction.

The polishing agent supply source 65 includes a polishing agent storage tank, a liquid feed pump, or the like. The polishing agent supply source 65 supplies the polishing agent to the processing point, when the wafer 2 is polished, through the through hole 65a during polishing. The through hole 65a is formed to pass through the center positions of the spindle 62, the mount 63, and the polishing pad 64. The polishing agent is, for example, a slurry that causes an oxidation reaction on the front surface of the wafer 2, and the polishing device 60 polishes the wafer 2 by so-called chemical mechanical polishing (CMP). The polishing agent contains an oxidizing agent and a pH adjuster, and is, for example, a mixed liquid of sodium permanganate and lanthanum nitrate. Although the polishing pad 64 contains abrasive grains and the slurry does not contain abrasive grains in the embodiment, the polishing pad 64 may not contain abrasive grains and the slurry may contain abrasive grains, or both the polishing pad 64 and the slurry may contain abrasive grains.

The polishing device 60 further includes a control device 100 that controls operations of the holding table 51 and the spindle 62. The control device 100 includes a processor that performs calculation processing according to a program, and a memory such as a ROM and a RAM. The control device 100 can receive data on the impurity concentration acquired in the impurity concentration acquisition step S10. The control device 100 itself may acquire data related to the impurity concentration, that is, the control device 100 may have functions of the control device 12 and the control device 29 described above.

The control device 100 transmits a signal to the rotation drive source 71 and/or the inclination adjustment mechanism 72 to control the operation of the holding table 51. Specifically, the control device 100 adjusts a rotation speed, an inclination, or the like of the holding table 51.

The control device 100 transmits a signal to the rotation drive source 66 and/or the polishing feed mechanism 67 to control the operation of the spindle 62. Specifically, the control device 100 adjusts a rotation speed of the spindle 62 (the polishing pad 64), a processing feed amount, a processing feed speed (a polishing rate described later), or the like.

The polishing device 60 may further include an inclination adjustment mechanism for adjusting an inclination of the polishing pad 64, instead of or in addition to the inclination adjustment mechanism 72 for adjusting the inclination of the holding table 51. The control device 100 may transmit a signal to the inclination adjustment mechanism to adjust the inclination of the polishing pad 64 with respect to the holding table 51.

In the polishing step S50, while the holding table 51 and the spindle 62 are rotated, the spindle 62 is lowered to bring the polishing pad 64 into contact with the peeling surface 2a of the wafer 2, and the peeling surface 2a of the wafer 2 is polished by the polishing pad 64.

When the workpiece (wafer 2) doped with the impurity is polished, the polishing rate (processing amount per unit time) of the polishing device 60 changes according to the impurity concentration. For example, when the wafer 2 of the Si single crystal is polished, the polishing rate decreases as the impurity concentration of the wafer 2 increases. Since a polishing time increases as the polishing rate decreases, an edge portion of the wafer 2 that easily receives the pressure from the polishing pad 64 becomes thinner than necessary. Such a relationship between the impurity concentration and the polishing rate varies according to a material of the wafer 2 and a type of the impurity to be doped, and for example, when the wafer 2 of the SiC single crystal doped with nitrogen is polished, the polishing rate increases as the impurity concentration of the wafer 2 increases. As described above, since the polishing rate changes according to the impurity concentration of the wafer 2, a thickness of the wafer 2 after polishing is not uniform.

Therefore, in the polishing step S50, the peeling surface 2a of the wafer 2 is polished and planarized based on the data on the impurity concentration acquired in the impurity concentration acquisition step S10.

As an example, in the polishing step S50, a contact condition of the polishing pad 64 with the wafer 2 is changed based on the average value of the impurity concentration as the data on the impurity concentration acquired in the impurity concentration acquisition step S10.

The contact condition includes, for example, at least one among a rotation speed of at least one of the polishing pad 64 and the holding table 51, an inclination of at least one of the polishing pad 64 and the holding table 51, a contact time (that is, polishing time) for which the polishing pad 64 and the wafer 2 are brought into contact with each other, and a pressing force of the polishing pad 64 against the wafer 2. The control device 100 changes at least one of the rotation speed, the inclination, the contact time, and the pressing force based on the average value of the impurity concentration of the wafer 2 to be polished such that the thickness of the wafer 2 becomes uniform.

In addition to or instead of the above-described conditions, the contact condition may include at least one of a temperature of the cooling water at the processing point, a temperature of the polishing agent supplied from the polishing agent supply source 65, and a composition of the polishing agent. The cooling water at the processing point is cooling water flowing through the cooling flow path provided in the holding table 51 and the polishing pad 64 described above. The control device 100 changes at least one of the temperature of the cooling water, the temperature of the polishing agent, and the composition of the polishing agent based on the average value of the impurity concentration of the wafer 2 to be polished such that the thickness of the wafer 2 becomes uniform. As an example, the change in the composition of the polishing agent as the contact condition adjusts a concentration of the oxidizing agent or the pH adjuster contained in the polishing agent.

The control device 100 may acquire the rotation speed, the inclination, the contact time, the pressing force, the temperature of the cooling water, the temperature of the polishing agent, and the composition of the polishing agent described above by calculation based on the average value of the impurity concentration, or may acquire them by referring to a predetermined map stored in advance.

In the polishing step S50, the contact condition of the polishing pad 64 with the wafer 2 may be changed based on the distribution of the impurity concentration instead of the average value of the impurity concentration as the data on the impurity concentration. That is, in the polishing step S50, the contact condition may be changed such that at least one of the rotation speed, the inclination, the contact time, the pressing force, the temperature of the cooling water, the temperature of the polishing agent, and the composition of the polishing agent is different between the region having a high impurity concentration and the region having a low impurity concentration.

Specifically, as an example, in the polishing step S50, the peeling surface 2a of the wafer 2 may be polished by applying a predetermined pressure distribution to the pressing force from the polishing pad 64 to the wafer 2 based on the distribution of the impurity concentration. For example, the polishing device 60 further includes an airbag that applies a distribution to the pressing force, and applies the predetermined pressure distribution to the pressing force from the polishing pad 64 to the wafer 2 by partially changing an air pressure of the airbag.

In another example, in the polishing step S50, the peeling surface 2a of the wafer 2 may be polished by applying a temperature distribution to the cooling water flowing through the cooling flow path provided in the polishing pad 64 and/or the holding table 51 based on the distribution of the impurity concentration. For example, a plurality of cooling flow paths may be provided, and cooling water having different temperatures may flow between a cooling flow path corresponding to the region having a high impurity concentration of the wafer 2 and a cooling flow path corresponding to the region having a low impurity concentration. The temperature distribution may be applied to the cooling water by circulating the cooling water in the order from the cooling flow path corresponding to the region having the high impurity concentration of the wafer 2 to the cooling flow path corresponding to the region having the low impurity concentration (or in the reverse order).

As described above, since the peeling surface 2a of the wafer 2 is polished and planarized based on the data on the impurity concentration in the polishing step S50, the variation in the thickness of the wafer 2 can be reduced in the polishing step S50. As a result, the thickness of the manufactured wafer 2 can be made uniform.

### Second Embodiment

A processing method according to a second embodiment of the present disclosure will be described.

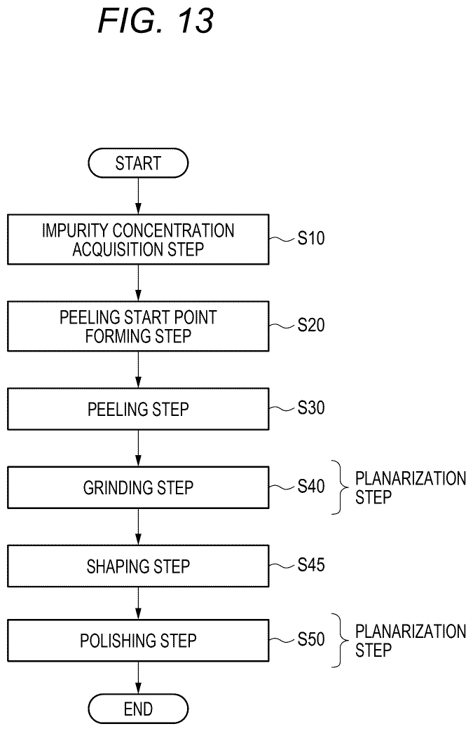

FIG. 13 is a flowchart showing the processing method according to the second embodiment. The processing method according to the second embodiment includes the impurity concentration acquisition step S10, the peeling start point forming step S20, the peeling step S30, the grinding step S40, a shaping step S45 of shaping a shape of the polishing pad 64 based on the distribution of the impurity concentration which is the data acquired in the impurity concentration acquisition step S10, and the polishing step S50 of bringing the polishing pad 64 shaped in the shaping step S45 into contact with the peeling surface 2a of the ground wafer 2 to polish the peeling surface 2a. The impurity concentration acquisition step S10, the peeling start point forming step S20, the peeling step S30, and the grinding step S40 are the same as those in the first embodiment, and repeated description thereof will be omitted.

### Shaping Step

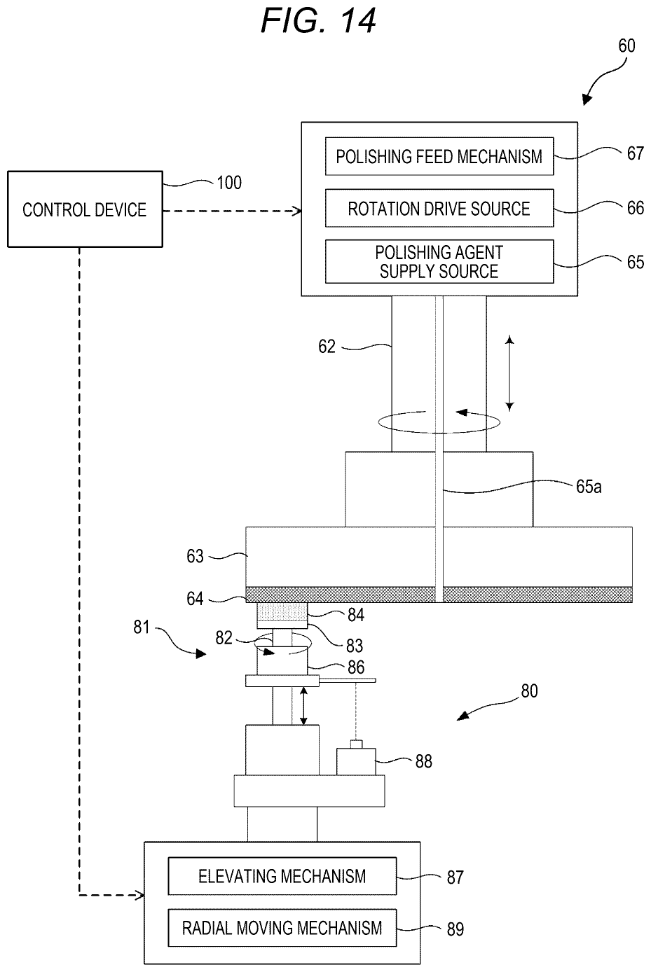

FIG. 14 is a schematic configuration diagram showing a configuration of a dressing mechanism 80 for performing the shaping step S45. The dressing mechanism 80 shapes the shape of the polishing surface of the polishing pad 64 before the polishing step S50.

The dressing mechanism 80 includes a dressing unit 81 that shapes the shape of the polishing surface of the polishing pad 64, an elevating mechanism 87 that moves the dressing unit 81 in the vertical direction, a displacement measuring instrument 88 that measures a displacement in the vertical direction of the dressing unit 81 due to the elevating mechanism 87, and a radial moving mechanism 89 that moves the dressing unit 81 along a radial direction of the polishing pad 64.

The dressing unit 81 includes a spindle 82 that extends in the vertical direction and is rotatably provided, a mount 83 fixed to an upper end of the spindle 62, a disk-shaped dressing plate 84 fixed to an upper end of the mount 83, and a rotation drive source 86 that has a motor and rotates the spindle 82.

The dressing plate 84 is formed by bonding particles such as diamonds to the front surface. The dressing plate 84 has a disk shape having a diameter smaller than that of the polishing pad 64, and faces the polishing pad 64 when the polishing pad 64 is shaped.

Center positions of the spindle 82, the mount 83, and the dressing plate 84 in the radial direction substantially coincide with each other, that is, the rotation axes thereof substantially coincide with each other. The rotation drive source 86 rotates the spindle 82 to rotate the mount 83 and the dressing plate 84 fixed to an upper end of the spindle 82.

The elevating mechanism 87 includes a ball screw, a motor, or the like. The dressing plate 84 is moved toward or away from the polishing pad 64 by moving the dressing unit 81 in the vertical direction.

The radial moving mechanism 89 includes a ball screw, a motor, or the like. The radial moving mechanism 89 moves the dressing unit 81 along the radial direction of the polishing pad 64. Accordingly, a contact position in the radial direction between the dressing plate 84 and the polishing pad 64 can be changed.

The control device 100 can also control the dressing mechanism 80 in addition to the polishing device 60. The control device 100 controls the rotation drive source 86, the elevating mechanism 87, and/or the radial moving mechanism 89, and controls an operation of the dressing plate 84. The control device 100 may simultaneously control the polishing device 60 when controlling the dressing mechanism 80.

The dressing mechanism 80 may further include an inclination adjustment mechanism that adjusts an inclination of the dressing plate 84. The control device 100 may control the inclination adjustment mechanism to adjust the inclination of the dressing plate 84.

First, in the shaping step S45, the dressing plate 84 and the polishing pad 64 are brought into contact with each other while the dressing plate 84 and the polishing pad 64 are rotated. Specifically, the control device 100 controls the elevating mechanism 87 of the dressing mechanism 80 to bring the dressing plate 84 close to the polishing pad 64. The control device 100 may control the polishing feed mechanism 67 of the polishing device 60 to bring the polishing pad 64 close to the dressing plate 84, or may control both the polishing feed mechanism 67 and the elevating mechanism 87 to bring the dressing plate 84 and the polishing pad 64 close to each other.

Next, in the shaping step S45, the dressing plate 84 and the polishing pad 64 are relatively moved in the radial direction in a state where the dressing plate 84 and the polishing pad 64 are in contact with each other. Specifically, the control device 100 controls the radial moving mechanism 89 of the dressing mechanism 80 to move the dressing plate 84 in the radial direction with respect to the polishing pad 64. When the polishing pad 64 is movable in the radial direction, the control device 100 may move the polishing pad 64 in the radial direction with respect to the dressing plate 84.

As described above, when the workpiece (wafer 2) doped with the impurity is polished, the polishing rate of the polishing device 60 changes according to the impurity concentration. For example, in the region (facet region F) where the impurity concentration of the wafer 2 of the SiC single crystal is high, the polishing rate is higher than in the region (non-facet region) where the impurity concentration of the wafer 2 is low. Therefore, when the wafer 2 is polished with the flat polishing pad 64, the facet region F may be thinner than the non-facet region. As a result, the thickness of the wafer 2 after polishing is not uniform.

Therefore, in the shaping step S45, before the polishing step S50, the shape of the polishing pad 64 is shaped based on the distribution of the impurity concentration, which is the data acquired in terms of the impurity concentration.

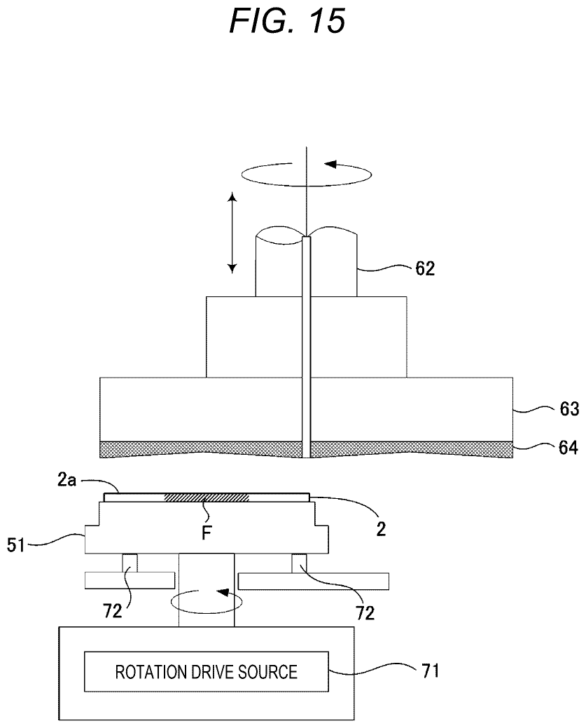

FIG. 15 is a schematic view showing an example of the shaped polishing pad 64. It should be noted that the shape of the polishing pad 64 is exaggerated as compared with an actual thickness of the polishing pad 64.

In the shaping step S45, the shape of the polishing pad 64 is shaped such that a protrusion amount toward the wafer 2 differs between a portion in contact with the facet region F of the wafer 2 and a portion in contact with the non-facet region. Specifically, in the case of the wafer 2 of the SiC single crystal, in the shaping step S45, the shape of the polishing pad 64 is shaped such that the portion in contact with the non-facet region of the wafer 2 has a shape protruding toward the wafer 2 more than the portion in contact with the facet region F. In the example shown here, the facet region F is formed in the central portion of the wafer 2, and the non-facet region is formed outward in the radial direction of the facet region F. The polishing is performed in a state where the rotation axis of the polishing pad 64 and the rotation axis of the holding table 51 are shifted from each other.

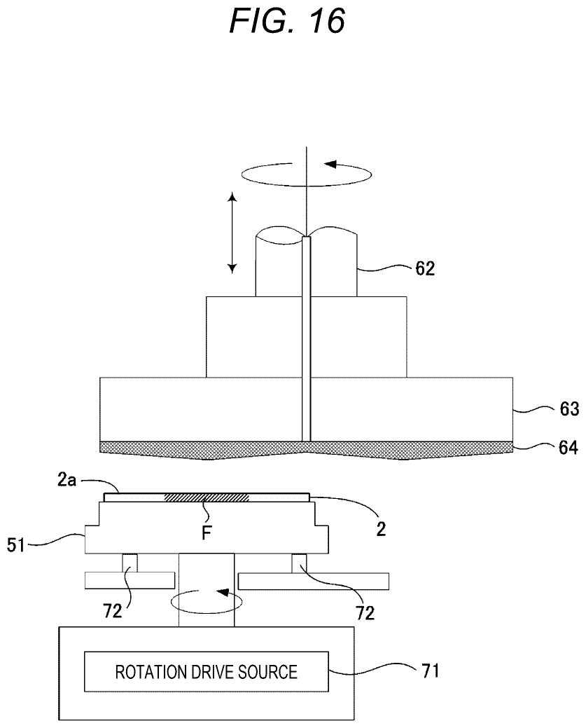

In the case of the wafer 2 of the Si single crystal, the polishing rate in the facet region F of the wafer 2 is lower than that in the non-facet region of the wafer 2. Therefore, as shown in FIG. 16, in the shaping step S45, the shape of the polishing pad 64 is shaped such that the portion in contact with the facet region F of the wafer 2 of the Si single crystal has a shape protruding toward the wafer 2 more than the portion in contact with the non-facet region.

With such a shape of the polishing pad 64, since the polishing pad 64 first comes into contact with the region where the polishing rate is low, it is possible to prevent a variation in the thickness of the wafer 2 between the facet region F and the non-facet region.

### Polishing Step

In the polishing step S50, the polishing pad 64 shaped in the shaping step S45 is brought into contact with the peeling surface 2a of the wafer 2 so as to be polished and planarized.

As described above, in the second embodiment, since the peeling surface 2a of the wafer 2 is polished and planarized based on the data on the impurity concentration in the polishing step S50, the variation in the thickness of the wafer 2 can be reduced in the polishing step S50. As a result, the thickness of the manufactured wafer 2 can be made uniform.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the embodiments described above may be freely combined without departing from the gist of the disclosure.

For example, in the processing method of each embodiment described above, an example in which the polishing step S50 is performed based on the data on the impurity concentration of the wafer 2 has been described, but the present disclosure is not limited thereto. For example, the processing method may perform the grinding step S40 based on the data on the impurity concentration of the wafer 2. That is, in the grinding step S40, the peeling surface 2a of the wafer 2 may be ground and planarized based on the data on the impurity concentration of the wafer 2 acquired in the impurity concentration acquisition step S10. In this case, the grindstones 56 are an example of the planarization processing unit in the present disclosure. Similarly, the data used in the grinding step S40 includes the average value of the impurity concentration and/or the distribution of the impurity concentration.

More specifically, in the grinding step S40, the contact condition with the wafer 2 in the grinding step S40 may be changed based on the data on the impurity concentration acquired in the impurity concentration acquisition step S10. The contact condition includes, for example, at least one among the rotation speed of at least one of the grindstone 56 and the holding table 51, the inclination of at least one of the grindstone 56 and the holding table 51, a feed speed at which the grindstones 56 cut into the wafer 2, and the temperature of the cooling water.

For example, although the impurity concentration acquisition step S10 is performed on the ingot 1 in the above-described embodiments, the present disclosure is not limited thereto, and the impurity concentration acquisition step S10 may be performed on the wafer 2 peeled from the ingot 1. That is, the impurity concentration acquisition step S10 may be performed after the peeling step S30.

In the above-described embodiments, the wafer 2 is peeled from the ingot 1 by the laser beam irradiation mechanism 30 and the peeling device 40, but the present disclosure is not limited thereto. For example, the wafer 2 may be obtained by slicing the ingot 1 to a predetermined thickness by a wire saw. In this case, the impurity concentration acquisition step S10 may be performed on the wafer 2 obtained from the ingot 1 by the wire saw.

The present specification describes at least the following matters. Corresponding components or the like in each embodiment described above are shown in parentheses as an example, but the present disclosure is not limited thereto.
(1) A processing method including:
an impurity concentration acquisition step (impurity concentration acquisition step S10) of acquiring data on an impurity concentration of a workpiece (ingot 1, wafer 2); and
a planarization step (grinding step S40, polishing step S50) of planarizing one surface (peeling surface 2a) of the workpiece held on a holding table (holding table 51) by grinding or polishing the one surface with a planarization processing unit (grindstone 56, polishing pad 64), in which
the one surface of the workpiece is planarized in the planarization step based on the data acquired in the impurity concentration acquisition step.

When a workpiece doped with an impurity in advance is planarized, a planarization rate in the planarization step changes according to the impurity concentration, and the workpiece may not be planarized to a uniform thickness. According to (1), the one surface of the workpiece is planarized in the planarization step based on the data on the impurity concentration acquired in the impurity concentration acquisition step, so that the variation in the thickness of the workpiece can be reduced in the planarization step.
(2) The processing method according to (1), in which
in the planarization step, a contact condition of the planarization processing unit with the workpiece is changed based on the data acquired in the impurity concentration acquisition step.

According to (2), by changing the contact condition with the workpiece based on the data acquired in the impurity concentration acquisition step, the variation in the thickness of the workpiece in the planarization step can be reduced.
(3) The processing method according to (2), in which
the contact condition includes at least one among
   a rotation speed of at least one of the planarization processing unit and the holding table,
   an inclination of at least one of the planarization processing unit and the holding table,
   a contact time for which the planarization processing unit and the workpiece are brought into contact with each other,
   a pressing force of the planarization processing unit against the workpiece,
   a temperature of cooling water flowing through a cooling flow path, which is provided in the planarization processing unit and/or the holding table and is capable of cooling a processing point of the workpiece,
   a temperature of a polishing agent supplied to the processing point, and
   a composition of the polishing agent supplied to the processing point.

According to (3), it is possible to reduce the variation in the thickness of the workpiece in the planarization step by appropriately changing the contact condition.
(4) The processing method according to (2) or (3), in which
the data acquired in the impurity concentration acquisition step is an average value of the impurity concentration of the workpiece.

According to (4), the variation in the thickness of the workpiece in the planarization step can be reduced by changing the contact condition based on the average value of the impurity concentration of the workpiece.
(5) The processing method according to (1), in which
the planarization step is a polishing step (polishing step S50) of polishing the one surface of the workpiece by a polishing pad (polishing pad 64), and
in the polishing step, the one surface of the workpiece is planarized by applying a predetermined pressure distribution to a pressing force from the polishing pad to the workpiece based on a distribution of the impurity concentration which is the data acquired in the impurity concentration acquisition step.

A polishing rate differs between a region having a high impurity concentration and a region having a low impurity concentration in the workpiece. According to (5), the variation in the thickness of the workpiece can be reduced by changing the pressing force from the polishing pad to the workpiece, between the region having the high impurity concentration and the region having the low impurity concentration.
(6) The processing method according to (1), in which
in the planarization step, the one surface of the workpiece is planarized by applying a temperature distribution to cooling water flowing through a plurality of cooling flow paths, which are provided in the planarization processing unit and/or the holding table and are capable of cooling a processing point of the workpiece, based on a distribution of the impurity concentration which is the data acquired in the impurity concentration acquisition step.

According to (6), the variation in the thickness of the workpiece can be reduced by changing a temperature of the cooling water, between a region having a high impurity concentration and a region having a low impurity concentration.
(7) The processing method according to (1), in which
the planarization step is a polishing step (polishing step S50) of polishing the one surface of the workpiece by a polishing pad (polishing pad 64),
the processing method further includes a shaping step (shaping step S45) of shaping a shape of the polishing pad based on a distribution of the impurity concentration, which is the data acquired in the impurity concentration acquisition step, before the polishing step, and
in the polishing step, the one surface of the workpiece is polished by the polishing pad shaped in the shaping step.

A polishing rate differs between a region having a high impurity concentration and a region having a low impurity concentration in the workpiece. According to (7), the shape of the polishing pad can be shaped based on the distribution of the impurity concentration, and the shape of the polishing pad for polishing the region having the high impurity concentration and the shape of the polishing pad for polishing the region having the low impurity concentration can be different. Therefore, the workpiece can be polished to a uniform thickness in the polishing step.
(8) The processing method according to (7), in which
in the shaping step, the shape of the polishing pad is shaped such that a protrusion amount toward the workpiece differs between a portion in contact with a region (facet region F) having a high impurity concentration of the workpiece and a portion in contact with a region (non-facet region) having a low impurity concentration.

According to (8), in the shaping step, the shape of the polishing pad is shaped such that the protrusion amount of the polishing pad differs between the portion in contact with the region having the high impurity concentration of the workpiece and the portion in contact with the region having the low impurity concentration. Thus, in the polishing step, the workpiece can be polished to a uniform thickness.
(9) The processing method according to any one of (1) to (8), in which
in the impurity concentration acquisition step, an electric resistance value of the workpiece is measured, and the data on the impurity concentration is acquired based on the electric resistance value.

According to (9), the data on the impurity concentration of the workpiece can be acquired by using the electric resistance value of the workpiece which differs according to the impurity concentration.
(10) The processing method according to any one of (1) to (8), in which
in the impurity concentration acquisition step, the workpiece is irradiated with an excitation light having a predetermined wavelength, and the data on the impurity concentration is acquired based on a detection result of a fluorescence generated by the excitation light.

According to (10), the data on the impurity concentration of the workpiece can be acquired by using the fluorescence generated by irradiating the workpiece with the excitation light.
(11) The processing method according to any one of (1) to (8), in which
in the impurity concentration acquisition step, the workpiece is irradiated with a light having permeability, and the data on the impurity concentration is acquired based on a transmittance of the light.

According to (11), the data on the impurity concentration of the workpiece can be acquired by using the transmittance of the light with respect to the workpiece.
(12) A processing device (grinding device 50, polishing device 60) for processing one surface (peeling surface 2a) of a workpiece (wafer 2) held on a holding table (holding table 51), the processing device including:
a spindle (spindle 52, spindle 62) extending in a predetermined direction and rotatably provided;
a mount (mount 53, mount 63) fixed to a tip end of the spindle; and
a planarization processing unit (grindstone 56, polishing pad 64) fixed to the mount and configured to grind or polish the one surface of the workpiece to planarize the one surface, in which
the processing device planarizes the one surface of the workpiece by the planarization processing unit based on data on an impurity concentration of the workpiece.

When a workpiece doped with an impurity in advance is planarized, a planarization rate changes according to the impurity concentration, and the workpiece may not be planarized to a uniform thickness. According to (12), since the processing device planarizes the one surface of the workpiece based on the data on the impurity concentration of the workpiece, the variation in the thickness of the workpiece can be reduced.
(13) The processing device according to (12), in which
the processing device changes a contact condition of the planarization processing unit with the workpiece based on the data on the impurity concentration of the workpiece.

According to (13), by changing the contact condition with the workpiece based on the data on the impurity concentration, the variation in the thickness of the workpiece can be reduced when the workpiece is planarized.
(14) The processing device according to (12), including:
a polishing device (polishing device 60) including the spindle, the mount, and a polishing pad (polishing pad 64) that is the planarization processing unit; and
a dressing mechanism (dressing mechanism 80) configured to shape a shape of the polishing pad based on the data on the impurity concentration of the workpiece, in which
the polishing device polishes the one surface of the workpiece by the polishing pad shaped by the dressing mechanism.

A polishing rate differs between a region having a high impurity concentration and a region having a low impurity concentration in the workpiece. According to (12), the shape of the polishing pad can be shaped based on a distribution of the impurity concentration, and the shape of the polishing pad for polishing the region having the high impurity concentration and the shape of the polishing pad for polishing the region having the low impurity concentration can be different. Therefore, the polishing device can polish the workpiece to a uniform thickness.

The processing device in (10) to (12) described above corresponds to the polishing device 60, the grinding device 50, or a combined device of the polishing device 60 and the dressing mechanism 80 in each of the embodiments described above.

### REFERENCE SIGNS LIST

1: ingot (workpiece)
2: wafer (workpiece)
50: grinding device (processing device)
51: holding table
52: spindle
53: mount
56: grindstone (planarization processing unit)
60: polishing device (processing device)
62: spindle
63: mount
64: polishing pad (planarization processing unit)
80: dressing mechanism (processing device)
S10: impurity concentration acquisition step
S40: grinding step (planarization step)
S45: shaping step
S50: polishing step (planarization step)

What is claimed is:

1. A processing method comprising:
acquiring data on an impurity concentration of a workpiece; and
planarizing one surface of the workpiece held on a holding table by grinding or polishing the one surface with a planarization processor, wherein
in the planarizing, the one surface of the workpiece is planarized based on the data acquired in the acquiring.

2. The processing method according to claim 1, wherein
in the planarizing, a contact condition of the planarization processor with the workpiece is changed based on the data acquired in the acquiring.

3. The processing method according to claim 2, wherein
the contact condition includes at least one among
a rotation speed of at least one of the planarization processor and the holding table,
an inclination of at least one of the planarization processor and the holding table,
a contact time for which the planarization processor and the workpiece are brought into contact with each other,
a pressing force of the planarization processor against the workpiece,
a temperature of cooling water flowing through a cooling flow path, which is provided in at least one of the planarization processor or the holding table and is capable of cooling a processing point of the workpiece,
a temperature of a polishing agent supplied to the processing point, and
a composition of the polishing agent supplied to the processing point.

4. The processing method according to claim 2, wherein
the data acquired in the acquiring is an average value of the impurity concentration of the workpiece.

5. The processing method according to claim 1, wherein
the planarizing is polishing the one surface of the workpiece by a polishing pad, and
in the polishing by the polishing pad, the one surface of the workpiece is planarized by applying a predetermined pressure distribution to a pressing force from the polishing pad to the workpiece based on a distribution of the impurity concentration which is the data acquired in the acquiring.

6. The processing method according to claim 1, wherein
in the planarizing, the one surface of the workpiece is planarized by applying a temperature distribution to cooling water flowing through a plurality of cooling flow paths, which are provided in at least one of the planarization processor or the holding table and are capable of cooling a processing point of the workpiece, based on a distribution of the impurity concentration which is the data acquired in the acquiring.

7. The processing method according to claim 1, wherein
the planarizing is polishing the one surface of the workpiece by a polishing pad,
the processing method further comprises: shaping a shape of the polishing pad based on a distribution of the impurity concentration, which is the data acquired in the acquiring, before the polishing by the polishing pad, and
in the polishing by the polishing pad, the one surface of the workpiece is polished by the polishing pad shaped in the shaping.

8. The processing method according to claim 7, wherein
in the shaping, the shape of the polishing pad is shaped such that a protrusion amount of the polishing pad toward the workpiece differs between a portion in contact with a region having a higher impurity concentration of the workpiece and a portion in contact with a region having a lower impurity concentration of the workpiece.

9. The processing method according to claim 1, wherein
in the acquiring, an electric resistance value of the workpiece is measured, and the data on the impurity concentration is acquired based on the electric resistance value.

10. The processing method according to claim 2, wherein
in the acquiring, an electric resistance value of the workpiece is measured, and the data on the impurity concentration is acquired based on the electric resistance value.

11. The processing method according to claim 3, wherein
in the acquiring, an electric resistance value of the workpiece is measured, and the data on the impurity concentration is acquired based on the electric resistance value.

12. The processing method according to claim 1, wherein
in the acquiring, the workpiece is irradiated with an excitation light having a predetermined wavelength, and the data on the impurity concentration is acquired based on a detection result of a fluorescence generated by the excitation light.

13. The processing method according to claim 2, wherein
in the acquiring, the workpiece is irradiated with an excitation light having a predetermined wavelength, and the data on the impurity concentration is acquired based on a detection result of a fluorescence generated by the excitation light.

14. The processing method according to claim 3, wherein
in the acquiring, the workpiece is irradiated with an excitation light having a predetermined wavelength, and the data on the impurity concentration is acquired based on a detection result of a fluorescence generated by the excitation light.

15. The processing method according to claim 1, wherein
in the acquiring, the workpiece is irradiated with a light having permeability, and the data on the impurity concentration is acquired based on a transmittance of the light.

16. The processing method according to claim 2, wherein
in the acquiring, the workpiece is irradiated with a light having permeability, and the data on the impurity concentration is acquired based on a transmittance of the light.

17. A processing device for processing one surface of a workpiece held on a holding table, the processing device comprising:
a spindle extending in a predetermined direction and rotatably provided;
a mount fixed to a tip end of the spindle; and
a planarization processor fixed to the mount and configured to grind or polish the one surface of the workpiece to planarize the one surface, wherein
the processing device planarizes the one surface of the workpiece by the planarization processor based on data on an impurity concentration of the workpiece.

18. The processing device according to claim 17, wherein
the processing device changes a contact condition of the planarization processor with the workpiece based on the data on the impurity concentration of the workpiece.

19. The processing device according to claim 17, comprising:
a polishing device including the spindle, the mount, and a polishing pad that is the planarization processor; and
a dressing mechanism configured to shape a shape of the polishing pad based on the data on the impurity concentration of the workpiece, wherein
the polishing device polishes the one surface of the workpiece by the polishing pad shaped by the dressing mechanism.

20. A substrate manufacturing method for manufacturing a substrate from a workpiece by planarizing, by the processing method according to claim 1, the one surface of the workpiece.
